(19) United States
(12) Patent Application Publication
(10) Pub. No.: US 2002/0135059 A1
(43) Pub. Date: Sep. 26, 2002

(54) Chip packaging structure

(76) Inventor: In-De Ou, Kaohsuing (TW)

Correspondence Address: J.C. Patents, Inc., 4 Venture, Suite 250, Irvine, CA, 92618, US

(21) Appl. No.: 09/841,935

(22) Filed: Apr. 25, 2001

(30) Foreign Application Priority Data
Mar. 20, 2001 (TW) 90106421

(51) Int. Cl. H01L 23/48

(52) U.S. Cl. 257/690

(57) ABSTRACT

A packaging structure at least comprises: a printed circuit substrate having an insulating structure made of high polymer composite material and a trace conductor structure interlacing within the insulating structure; a plurality of leads arranged on the periphery of the printed circuit substrate and connected to the printed circuit substrate; a chip bonded and connected onto the printed circuit substrate; and an encapsulant material that encapsulates the chip, the printed circuit substrate, and inner portions of the leads.

### CROSS-REFERENCE TO RELATED APPLICATION

This application claims the priority benefit of Taiwan application serial no. 90106421, filed Mar. 20, 2001.

### BACKGROUND OF THE INVENTION

1. Field of the Invention

The invention relates to a packaging structure. More particularly, the invention relates to a leadframe or printed circuit substrate packaging structure.

2. Description of the Related Art

As electronic technology progresses, the emphasis is more particularly made to the miniaturization of electronic products. This miniaturization results in a structure of electronic products that is increasingly complicated and denser. In semiconductor manufacturing, this miniaturization is already embodied by a mass production of semiconductor devices that have conductive lines of 0.18 micron wide. With respect to the chips which surface is substantially reduced, various packaging structures, such as chip scale package (CSP), multi-chip module (MCM), are consequently developed to adapt to the chips. More specifically, multi-chip module (MCM) packaging type consists in packaging a plurality of chips carried by a single carrier. Since a plurality of chips are integrated within a single packaging structure, circuit space thus can be substantially reduced. The multi-chip module (MCM) package is suitable for use with a leadframe or a ball grid array (BGA) substrate.

Referring now to FIG. 1, a cross-sectional view schematically illustrates a conventional multi-chip module packaging structure. A conventional packaging structure 100 comprises a plurality of chips 120, a leadframe, a plurality of passive devices 150, and an encapsulant 160. The leadframe comprises a chip pad 130, and a plurality of leads 140 surrounding a periphery of the chip pad 130. Each chip 120 has an active surface 122 with a plurality of bonding pads 126 formed thereon and a corresponding back surface 124 by which the chip is bonded onto the chip pad 130. A plurality of bonding wires 170 electrically connect the chips 120 to one another and to the leads 140. The passive devices 150 are arranged and connected onto the leads 140. The encapsulant 160 encapsulates the chips 120, the chip pad 130, the passive device 150, the bonding wires 170, and inner portions 142 of the leads 140, while exposing outer portions 144 of the leads 140 that are to be connected to an external device.

In the multi-chip module packaging structure of FIG. 1, because the bonding wires can only connect bonding pads proximate to one another or bonding pads proximate to the leads, the arrangement of the bonding pads thus is substantially limited as well as the number of chips 120 that are packaged. Moreover, since the number of leads is conventionally less than 200, the number of passive devices 150 that can be connected to the leads is also limited.

Referring now to FIG. 2, a cross-sectional view schematically illustrates another conventional multi-chip module packaging structure. The conventional packaging structure 200 comprises a plurality of chips 220, a ceramic substrate 230, a plurality of leads 240, and an encapsulant 260. The ceramic substrate 230 has a ceramic surface 232 onto which are formed a plurality of chip-bonding pads 234 and a plurality of lead-bonding pads 236 located at the periphery of the surface 232 of the ceramic substrate 230. The plurality of chips 220, each having an active surface 222 onto which are formed a plurality of bonding pads 226 and a corresponding back surface 224, are bonded onto the ceramic substrate 230 by the back surface 224 thereof. A plurality of bonding wires 250 connect the bonding pads 226 of the chips 220 to the chip-bonding pads 234 of the ceramic substrate 230. Inner portions 242 of the leads 240 are connected onto the lead-bonding pads 236 of the ceramic substrate. The encapsulant 260 encapsulates the chips 220, the ceramic substrate 230, the bonding wires 250, and the inner portions 242 of the leads 240 while exposing outer portions 244 of the leads 240 for external connection.

With the packaging structure of FIG. 2, since the leads are directly bonded onto the ceramic substrate, the problems described above in connection with the packaging structure of FIG. 1 may be solved. However, because the encapsulant is usually made of polymer, a substantial thermal mismatch thus exists between the ceramic substrate and the polymer encapsulant, which renders the packaging structure not reliable to thermal stress. Besides, since the patterned trace layers within the ceramic substrate 230 are made of tungsten, which bonding to tin-lead alloys is poor, tin-lead alloys conventionally used for electrical connection thus cannot be used in the present packaging structure. To overcome this difficulty, a plating of nickel-gold is conventionally performed on the bonding pads of the ceramic substrate that are directed to electrical connection (chip-bonding pads 234 and lead-bonding pads 236) while a gold plating is also applied on the bonding portions of the leads. A crystal-conformal bonding then can be achieved between the gold plating of the leads with the nickel-gold of the bonding pads of the ceramic substrate. Such a process for packaging is however cumbersome and incompatible with a sought low cost and efficient packaging structure.

### SUMMARY OF THE INVENTION

A first aspect of the present invention is to provide a packaging structure that can increase the reliability of the packaging structure with respect to thermal stress.

A second aspect of the present invention is to provide a packaging structure that is simple to produce, lowers the manufacturing cost, and improve the efficiency of the manufacturing process.

To attain the foregoing and other aspects, the present invention, according to a first preferred embodiment, provides a packaging structure comprising: a printed circuit substrate having an insulating structure made of high polymer composite material and a trace conductor structure interlacing within the insulating structure; a plurality of leads arranged at the periphery of the printed circuit substrate and connected onto the printed circuit substrate; a chip bonded and connected onto the printed circuit substrate; and an encapsulant material that encapsulates the chip, the printed circuit substrate, and inner portions of the leads.

According to an embodiment of the present invention, the chip can be electrically connected to the printed circuit substrate by either wire-bonding or flip-chip fashion. Besides, the leads are connected to the printed circuit substrate via a plurality of bumps which material comprises either tin-lead alloys or conductive pastes. The material of the insulating structure comprises glass epoxy resins, bismaleimide-triazine (BT), epoxy, or polyimide. The packaging structure further comprises a passive device bonded and connected onto the printed circuit substrate, wherein the passive device is also encapsulated in the encapsulant material.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view schematically illustrating a first conventional multi-chip module packaging structure;

FIG. 2 is a cross-sectional view schematically illustrating a second conventional multi-chip module packaging structure;

FIG. 3 is a cross-sectional view schematically illustrating a multi-chip module packaging structure according to a first embodiment of the present invention; and

FIG. 4 is a cross-sectional view schematically illustrating a multi-chip module packaging structure according to a second embodiment of the present invention.

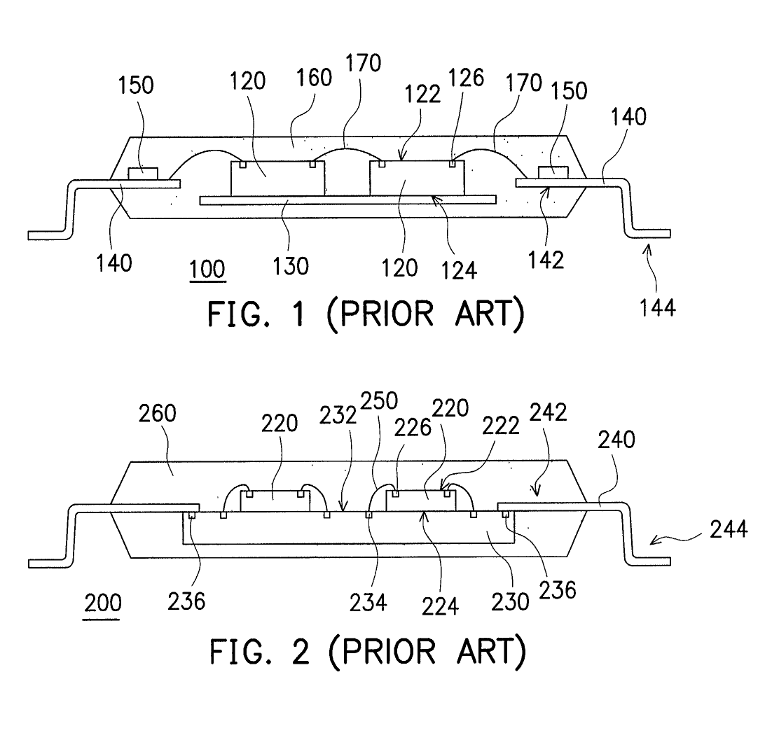

### DESCRIPTION OF THE PREFERRED EMBODIMENTS

The following detailed description of the embodiments and examples of the present invention with reference to the accompanying drawings is only illustrative and not limiting.

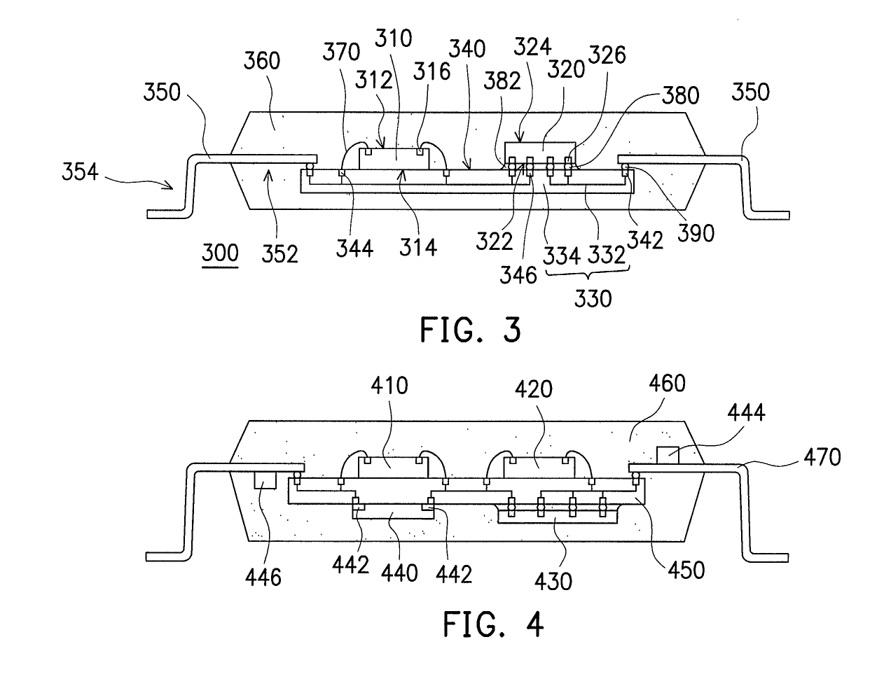

Referring now to FIG. 3, a cross-sectional view schematically illustrates a multi-chip module packaging structure according to a first preferred embodiment of the present invention. A multi-chip module packaging structure 300 comprises a plurality of chips 310, 320, a printed circuit substrate 330, a plurality of leads 350, and an encapsulant material 360. The printed circuit substrate 330 comprises a plurality of patterned trace layers alternately stacked with a plurality of insulating layers, and the insulating layers are provided with a plurality of conductive vias that interconnect two successive patterned trace layers. The insulating layers and patterned trace layers hence form an insulating structure 334 and a trace conductor structure 332 within the printed circuit substrate 330. The material of the insulating structure 334 can be, for example, glass epoxy resins (FR-4, FR-5), bismaleimide-triazine (BT), epoxy, or polyimide. The printed circuit substrate 330 is thus an organic substrate. Each of the patterned trace layers of the trace conductor structure 332 is defined by performing conventional photolithography and etching processes. A solder mask can be also deposited on the surface of the printed circuit substrate 330. The printed circuit substrate can be multi-layers or single layer, depending on the number of patterned trace layers and insulating layers that are stacked.

The printed circuit substrate 330 comprises a substrate surface 340 onto which are formed a plurality of lead-bonding pads 342, wire-bonding pads 344, and chip-bonding pads 346. The lead-bonding pads 342 are located at the periphery of the substrate surface 340. The first chip 310 and the second chip 320 have respectively a first back surface 314 and a second back surface 324, and respectively a first active surface 312 and second active surface 322. A first plurality of bonding pads 316 and a second plurality of bonding pads 326 are respectively formed on the first active surface 312 and second active surface 322 of the first and second chips 310 and 320. The first chip 310 is bonded onto the printed circuit substrate 330 by its first back surface 314, and connected via bonding-wires 370 to the wire-bonding pads 344 of the organic substrate. Differently, the second chip 320 is bonded onto the printed circuit substrate 330 by its second active surface 322, and connected to the chip-bonding pads 346 of the substrate via a plurality of first bumps 380 in flip-chip fashion. An underfill 382 is filled between the second active surface 322 and the substrate surface 340, thus encapsulating the first bumps 380. The leads 350 are connected onto the lead-bonding pads 342 of the substrate through a plurality of second bumps 390. The first and second bumps can be made of, for example, tin-lead alloys or conductive paste. The encapsulant material 360, made of polymer, covers the printed circuit substrate 330, the chips 310, 320, inner portions 352 of the leads 350, the first bumps 390, bonding wires 370, and underfill 382, while exposing outer portions 354 of the leads 350 used for external connection.

The above-described packaging structure has at least the following advantages. Because the coefficient of expansion of the insulating structure 334 is close to that of the encapsulant material 360, the packaging structure thus is advantageously more reliable with respect to thermal stress. Furthermore, the packaging structure of the present invention can be module-designed by, for example, splitting the packaging structure in a module comprising the printed circuit substrate 330 and another module comprising the leads 350. As a result, when, for example, the design of the chips 310, 320 changes, only the module comprising the printed circuit substrate 330 is modified. Thus, the manufacturing cost can be advantageously reduced. Another advantage is that since the insulating structure 334 of the printed circuit substrate, such as described above, is made of high polymer composite material, the printed circuit substrate 330 of the present invention, compared to a conventional substrate with a same number of patterned trace layers but with an insulating structure made of ceramic, thus is advantageously thinner. Moreover, in the present invention, the bonding of the bumps is performed by first, forming the bumps on the lead-bonding pads 342 of the printed circuit substrate by screen printing, then reflowing the formed bumps while attaching the leads 350 onto the bumps 390. Consequently, compared to the conventional bonding of the leads to the ceramic substrate such as shown in FIG. 2, the bonding of the present invention is lower-cost, without a plating of the leads.

Referring now to FIG. 4, a cross-sectional view schematically illustrates a multi-chip module packaging structure according to a second embodiment of the present invention. Not limited to the only packaging of two chips, the packaging structure of the present invention also can package a plurality of chips 410, 420, 430 and a plurality of passive devices 440 (cross-sectional view of FIG. 4 only shows one passive device 440) on both opposite surfaces of the printed circuit substrate 450. For example, such as illustrated in FIG. 4, the chips 410, 420 are connected to the organic printed circuit substrate 450 by wire bonding while the chip 430 is connected onto the printed circuit substrate 450 in flip-chip fashion. The passive devices 440 are connected via the contact pads 442 thereof onto the printed circuit substrate 450 by surface mounting technology. Other passive devices 444, 446 also can be bonded and connected onto both up and down surfaces of the leads 470. The above different passive devices and chips are encapsulated in an encapsulant material 460.

By packaging a substantial amount of devices, the above-described packaging structure of the second embodiment of the present invention thus advantageously has an improved density.

In summary, the foregoing description of examples and embodiments of the present invention reveals at least the following advantages. The packaging structure of the present invention is more reliable with respect to thermal stress because the material used for the organic substrate and the material used for the encapsulant have respective coefficients of expansion that are close to each other.

Furthermore, the packaging structure of the present invention can be module-designed by splitting the model of the packaging structure into a plurality of modules that comprise different parts of the structure; these modules then can be independently modified according to the demand, which advantageously reduces the manufacturing cost.

Furthermore, because the insulating structure of the printed circuit substrate is made of a high polymer composite material, the organic substrate of the present invention is therefore thinner than a conventional ceramic substrate for an identical number of patterned trace layers.

Moreover, since the bonding between the leads and the organic substrate is via bump-bonding without a plating process, the bonding process is lower cost than that of the conventional packaging.

Furthermore, the packaging structure of the present invention allows to package a plurality of chips and passive devices on both sides of the substrate and also on both sides of the leads, thus the density of the packaging structure can be substantially increased.

It will be apparent to those skilled in the art that various modifications and variations can be made to the structure of the present invention without departing from the scope or spirit of the invention.

What is claimed is:

1. A packaging structure, at least comprising:
a printed circuit substrate that comprises a trace conductor structure and an insulating structure made of high polymer composite material, the trace conductor structure interlacing between the insulating structure;
a plurality of leads that are arranged on a periphery of the printed circuit substrate and connected to the printed circuit substrate;
at least a chip that is bonded on a surface of the printed circuit substrate and electrically connected to the printed circuit substrate; and
an encapsulant material that encapsulates the chip, the printed circuit substrate, and a portion of the leads proximate to the printed circuit substrate.

2. The packaging structure of claim 1, wherein the chip is electrically connected to the printed circuit substrate by wire-bonding.

3. The packaging structure of claim 1, wherein the chip is electrically connected to the printed circuit substrate in flip-chip fashion.

4. The packaging structure of claim 1, wherein the leads are connected to the printed circuit substrate by a plurality of bumps which material is selected from a group that consists of tin-lead alloys and conductive paste.

5. The packaging structure of claim 1, wherein the material of the insulating structure is selected from a group that consists of glass epoxy resins, bismaleimide-triazine (BT), epoxy, and polyimide.

6. The packaging structure of claim 1, wherein the printed circuit substrate further carries a passive device electrically connected onto the printed circuit substrate and also encapsulated by the encapsulant material.

7. The packaging structure of claim 1, wherein the leads further carry a passive device connected to the leads and also encapsulated by the encapsulant material.

8. The packaging structure of claim 1, wherein the leads are connected onto the printed circuit substrate by first forming a plurality of bumps on the printed circuit substrate by screen printing, and then bonding the leads to the bumps by reflow of the bumps.
